(19) United States
(12) Patent Application Publication
(10) Pub. No.: US 2020/0194505 A1
(43) Pub. Date: Jun. 18, 2020

(54) ORGANIC LIGHT EMITTING DIODE DISPLAY

(71) Applicant: Wuhan China Star Optoelectronics Technology Co., Ltd., Wuhan (CN)

(72) Inventor: Yuejun TANG, Wuhan (CN)

(73) Assignee: Wuhan China Star Optoelectronics Technology Co., Ltd., Wuhan (CN)

(21) Appl. No.: 16/319,478

(22) PCT Filed: Jan. 7, 2019
(86) PCT No.: PCT/CN2019/070584

§ 371 Date: Jan. 22, 2019

(30) Foreign Application Priority Data
Dec. 12, 2018 (CN) 201811515170.8

(51) Int. Cl. H01L 27/32

(52) U.S. Cl. CPC H01L 27/323; H01L 27/3276; H01L 27/3246

(57) ABSTRACT

The present disclosure proposes an organic light emitting diode (OLED) display. The OLED display includes a substrate, a planar layer, a bonding terminal, a cathode node metal layer and a pixel definition layer arranged on the planar layer. A spacing member above the pixel definition layer is arranged on the cathode metal layer. The spacing member divides the cathode metal layer into two or more mutually independent sensing electrodes. Each of the sensing electrodes is electrically connected to the bonding terminal through a touch wire. The touch wire is arranged below the cathode metal layer.

### BACKGROUND

### 1. Field of the Disclosure

The present disclosure relates to the field of display technology, and more particularly, to an organic light emitting diode (OLED) display.

### 2. Description of the Related Art

An organic light emitting diode (OLED) display serving as a display device configured to show images has attracted a lot of attention. The OLED display is characteristic of autoluminescence and does not adopt a separate light source. Compared with a display device where a singular light source is adopted, the OLED display is more compact.

In the related art, to perform the function of touch control of the OLED display, one solution is to produce a touch screen and an OLED display screen separately. Afterwards, the touch screen is attached to the upper surface of the OLED display screen to form a complete OLED touch screen with optical transparent glue. Another solution is that a touch unit is manufactured above an encapsulating layer of the OLED display screen. However, the arrangement of the touch unit and signal lines of the touch unit proposed by the solutions tends to increase the thickness of the OLED touch screen or the manufacturing process of the OLED touch screen, which is not good to make the OLED touch screen compact.

### SUMMARY

In an organic light emitting diode (OLED) display, a touch unit and a signal lead for the touch unit will increase the thickness of the OLED touching screen or the manufacturing process of the OLED touching screen. It is not good for the OLED touching screen to become more compact.

The present disclosure proposes an organic light emitting diode (OLED) display. The OLED display includes a substrate, a buffer layer arranged on the substrate, a semiconductor layer arranged on the buffer layer, a gate insulating layer arranged on the buffer layer and covering the semiconductor layer, a first metal layer arranged on the gate insulating layer and comprising a gate metal line and a scanning line, an interlayer insulating layer arranged on the gate insulating layer and covering the first metal layer, a second metal layer arranged on the interlayer insulating layer and comprising a source-drain metal trace and a data line, a planar layer arranged on the interlayer insulating layer and covering the second metal layer, an anode metal layer and a pixel definition layer arranged on the planar layer, a cathode metal layer, arranged on the pixel definition layer, and a bonding terminal. A spacing member above the pixel definition layer is arranged on the cathode metal layer. The spacing member divides the cathode metal layer into two or more mutually independent sensing electrodes. Each of the sensing electrodes is electrically connected to the bonding terminal through a touch wire. The touch wire is arranged below one layer of the cathode metal layer.

Furthermore, the touch wire and the anode are arranged in the same layer and independent of each other. A first hole is arranged on the pixel definition layer; the sensing electrode is electrically connected to the touch wire through the first hole.

Furthermore, the anode metal layer comprises the anode and the touch wire. The touch wire and the anode are fabricated in the same manufacturing process.

Furthermore, the touch wire and the data line are arranged in the same layer and independent of each other. A second hole is arranged on the pixel definition layer and penetrates the pixel definition layer and the planar layer. The sensing electrode is electrically connected to the touch wire through the second hole.

Furthermore, the second metal layer comprises the data line and the touch wire. The touch wire and the data line are fabricated in the same manufacturing process.

Furthermore, the touch wire and the scanning line are arranged in the same layer and independent of each other. A third hole is arranged on the pixel definition layer and penetrates the pixel definition layer, the planar layer, and the interlayer insulating layer. The sensing electrode is electrically connected to the touch wire through the third hole.

Furthermore, the first metal layer comprises the scanning line and the touch wire. The touch wire and the scanning line are fabricated in the same manufacturing process.

Furthermore, the touch wires comprise two or more of the first metal layer, the second metal layer, and the anode metal layer. The metal layers arranged between different but adjacent layers in the touch wire are electrically connected through a joint hole. The metal layer arranged in the top layer of the touch wire is electrically connected to the corresponding sensing electrode through a fourth hole.

Furthermore, the touch wire which the sensing electrode away from the bonding terminal is connected to comprises two or more of the first metal layer, the second metal layer, and the anode metal layer.

Furthermore, the width of the touch wire which the sensing electrode is connected to is directly proportional to the distance between the sensing electrode and the bonding terminal.

The present disclosure brings some benefits. A cathode metal layer acts as a sensing electrode while a touch wire which is connected to the sensing electrode and a bonding terminal is arranged below the cathode metal layer. In this way, the thickness of the OLED display is reduced, thereby making the OLED display more compact. In addition, the touch wire and any one or two or more of the anode, the data line, and the scanning line are fabricated from the same materials in the same process, which is good to lessen the production processes and reducing the production cost. According to the distance between the touch wire and the bonding terminal, the width of the touch wire and the number of metal layer are adjusted flexibly, which is good to reduce the difference between different touch wires but enhancing the sensitivity of touch.

### BRIEF DESCRIPTION OF THE DRAWINGS

In order to more clearly illustrate the embodiments of the present disclosure or related art, the following figures will be described in the embodiments are briefly introduced. It is obvious that the drawings are merely some embodiments of the present disclosure, those of ordinary skill in this field can obtain other figures according to these figures without paying the premise.

FIG. 1 illustrates schematic diagram of sensing electrodes and bonding terminals according to an embodiment of the present disclosure.

FIG. 2 illustrates a cross sectional view of an OLED display according to a first embodiment of the present disclosure.

FIG. 3 illustrates a cross sectional view of an OLED display according to a second embodiment of the present disclosure.

FIG. 4 illustrates a cross sectional view of an OLED display according to a third embodiment of the present disclosure.

FIGS. 5 through 7 illustrate cross sectional views of an OLED display according to a fourth embodiment of the present disclosure.

The elements labeled in the Drawings are:

11 substrate; 12 buffer layer; 13 semiconductor layer, 14 gate insulating layer; 15 first metal layer 15; 151 gate metal line; 16 interlayer insulating layer; 17 second metal layer; 171 source-drain metal trace; 18 planar layer; 19 pixel definition layer; 191 spacing member; 21 anode metal layer 21; 22 light-emitting material layer 22; 23 cathode metal layer; 231 sensing electrode; 30 bonding terminal; 40 touch wires 40; 51 first hole; 52 second hole; 53 third hole; 54 fourth hole; 60 joint hole.

### DETAILED DESCRIPTION OF THE EMBODIMENTS

In the disclosure, it is should be understood that spatially relative terms, such as “center”, “longitudinal”, “lateral”, “length”, “width”, “above”, “below”, “front”, “back”, “left”, “right”, “horizontal”, “vertical”, “top”, “bottom”, “inner”, “outer”, “clockwise”, “counterclockwise”, “axial”, “radial”, “circumferential”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. The spatially relative terms are not limited to specific orientations depicted in the figures.

A touch unit and a signal lead for the touch unit increase the thickness of the OLED touch display of the related art or the process of manufacturing the OLED touch display of the related art, which is not good to make the OLED touch display compact. However, the above problem can be well dealt with based on the present disclosure.

In the present disclosure, the OLED display is an embedded touch display.

### Embodiment 1

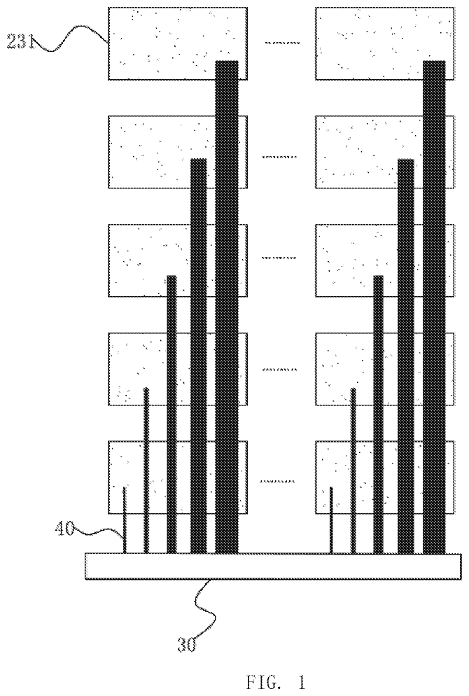

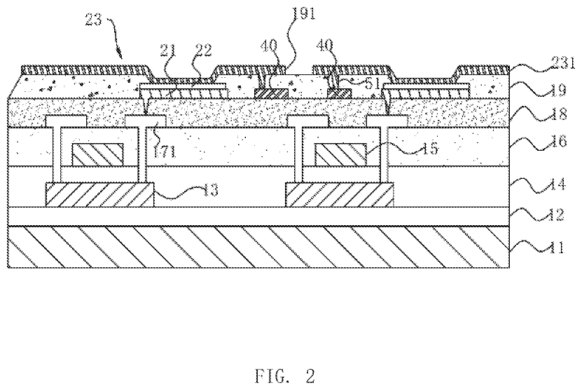

As illustrated in FIG. 1 and FIG. 2, an organic light emitting diode (OLED) display includes a substrate 11, a buffer layer 12, a semiconductor layer 13, a gate insulating layer 14, a first metal layer 15, an interlayer insulating layer 16, a second metal layer 17, and a planar layer 18. The substrate 11, the buffer layer 12, the semiconductor layer 13, the gate insulating layer 14, the first metal layer 15, the interlayer insulating layer 16, the second metal layer 17, and the planar layer 18 are sequentially disposed. A pixel definition layer 19 and a light-emitting layer are arranged on the planar layer 18.

The buffer layer 12 is arranged on the substrate 11. The semiconductor layer 13 is arranged on the buffer layer 12. The gate insulating layer 14 is arranged on the buffer layer 12 and covers the semiconductor layer 13. The first metal layer 15 is arranged on the gate insulating layer 14. The first metal layer 15 includes a gate metal line 151 and a scanning line. The interlayer insulating layer 16 is arranged on the gate insulating layer 14 and covers the first metal layer 15. The second metal layer 17 is arranged on the interlayer insulating layer 16. The second metal layer 17 includes a source-drain metal trace 171 and a data line. The planar layer 18 is arranged on the interlayer insulating layer 16 and covers the second metal layer 17. The light-emitting layer includes an anode metal layer 21, a light-emitting material layer 22, and a cathode metal layer 23.

The OLED display further includes a bonding terminal 30. A spacing member 191 above the pixel definition layer 19 is arranged on the cathode metal layer 23. The spacing member 191 divides the cathode metal layer 23 into two or more mutually independent sensing electrodes 231. Each of the sensing electrodes 231 is electrically connected to the bonding terminal through one of the touch wires 40. The touch wire is arranged below the cathode metal layer 23.

The cathode metal layer 23 serves as the sensing electrode 231. Meanwhile, the touch wire 40 which is connected to the sensing electrode 231 and the bonding terminal 30 is arranged below the cathode metal layer 23. In this way, the thickness of the OLED display is reduced, thereby making the OLED display compact.

Specifically, the anode metal layer 21 includes an anode. The touch wire 40 and the anode are arranged in the same layer and independent of each other. A first hole 51 is arranged on the pixel definition layer 19. The sensing electrode 231 is electrically connected to the touch wire 40 through the first hole 51.

FIG. 2 illustrates only one arrangement of the first hole 5. In another embodiment, a first hole 51 is arranged arbitrarily below a corresponding sensing electrode 231, which is not enumerated here.

The anode metal layer 21 includes the anode and the touch wire 40. The touch wire 40 and the anode are fabricated with the same materials in the same manufacturing process. In other words, less manufacturing processes are necessary, and less additional masks are required, which is good to reduce the production cost.

The width of the touch wire 40 which the sensing electrode 231 is connected to is directly proportional to the distance between the sensing electrode 231 and the bonding terminal 30.

The greater the distance between the sensing electrode 231 and the bonding terminal 30 is, the greater the width of the touch wire 40 which the sensing electrode 231 is connected to becomes. Therefore, the difference of resistors between different touch wires 40 is reduced while the sensitivity of touch improves.

### Embodiment 2

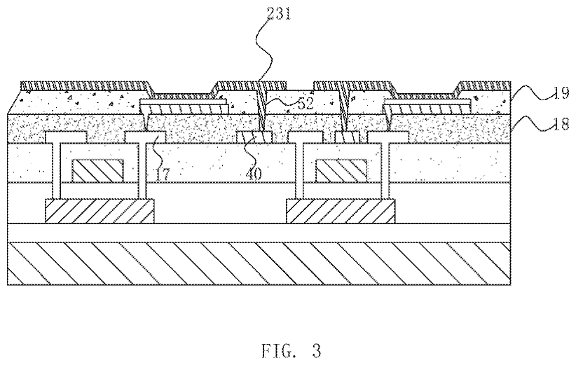

As illustrated in FIG. 3, a touch wire 40 adopted by the second embodiment is different from the touch wire 40 adopted by the first embodiment merely in arrangement and material.

The touch wire 40 and a data line are arranged in the same layer and independent of each other. A second hole 52 is arranged on a pixel definition layer 19. The second hole 52 penetrates the pixel definition layer 19 and a planar layer 18. A sensing electrode 231 is electrically connected to the touch wire 40 through the second hole 52.

A second metal layer 17 includes a data line and the touch wire 40. The touch wire 40 and the data line are fabricated in the same manufacturing process.

### Embodiment 3

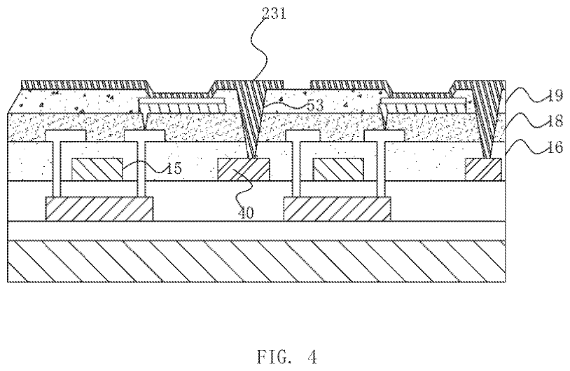

As illustrated in FIG. 4, a touch wire 40 adopted by the third embodiment is different from the touch wire 40 adopted by the first embodiment merely in arrangement and material.

Specifically, the touch wire 40 and a scanning line are arranged in the same layer and independent of each other. A third hole 53 is arranged on a pixel definition layer 19 and penetrates the pixel definition layer 19, a planar layer 18, and an interlayer insulating layer 16. A sensing electrode 231 is electrically connected to the touch wire 40 through the third hole 53.

The first metal layer 15 includes the scanning line and the touch wire 40. The touch wire 40 and the scanning line are fabricated in the same manufacturing process.

### Embodiment 4

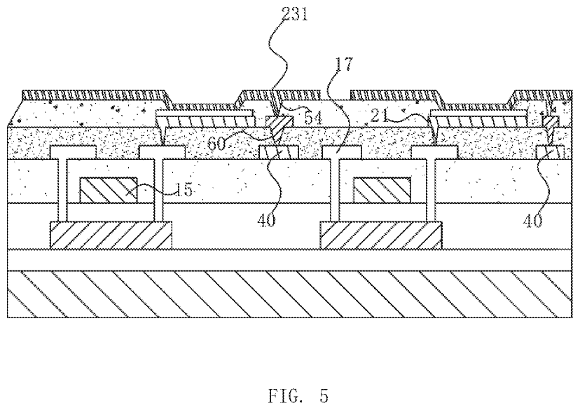

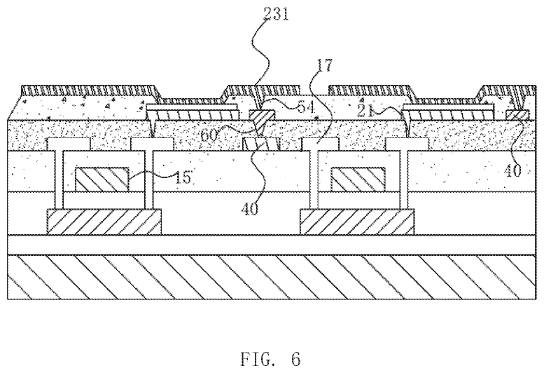

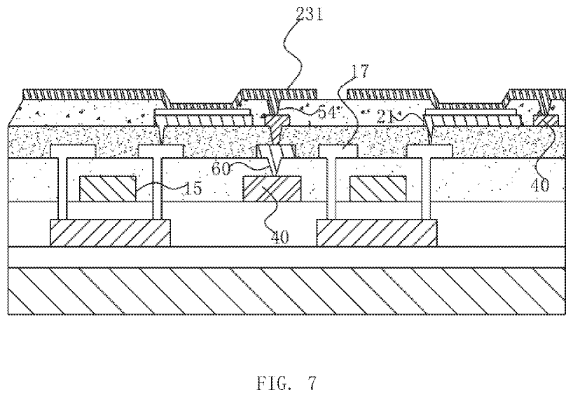

As illustrated in FIG. 5, FIG. 6, and FIG. 7, a touch wire 40 adopted by the fourth embodiment is different from the touch wire 40 adopted by the first embodiment merely in arrangement and material.

Specifically, the touch wires 40 include at least two layers selected from a first metal layer 15, a second metal layer 17, and an anode metal layer 21. In other words, the touch wires 40 are fabricated by two or more of the first metal layer 15, the second metal layer 17, and the anode metal layer 21.

The metal layers arranged between different but adjacent layers in one of the touch wires are electrically connected through a joint hole 60. The metal layer arranged in the top layer of the touch wire 40 is electrically connected to a corresponding sensing electrode 231 through a fourth hole 54.

Some of the touch wires 40 are fabricated by a multi-layered metal layer, which reduces the difference of resistors between different touch wires 40 and enhances the sensitivity of touch.

The touch wire 40 which the sensing electrode 231 away from the bonding terminal 30 is connected to includes two or more of the first metal layer 15, the second metal layer 17, and the anode metal layer 21.

As FIG. 5 illustrates, all of the touch wires 40 are fabricated by the second metal layer 17 and the anode metal layer 21. As FIG. 6 illustrates, some of the touch wires 40 are fabricated by the second metal layer 17 and the anode metal layer 21, and some of the touch wires 40 are fabricated by the anode metal layer 21. As FIG. 7 illustrates, some of the touch wires 40 are fabricated by the first metal layer 15, the second metal layer 17, and the anode metal layer 21, and some of the touch wires 40 are fabricated by the anode metal layer 21.

It is understood by the person skilled in the art that, in practical embodiments, the touch wire 40 may further be fabricated by a first metal layer 15, a second metal layer 17, and an anode metal layer 21 whether of the three, of both of the three, or one of the three, which is not enumerated here.

The present disclosure brings some benefits. A cathode metal layer 23 acts as a sensing electrode 231 while a touch wire 40 which is connected to the sensing electrode 231 and a bonding terminal 30 is arranged below the cathode metal layer 23. In this way, the thickness of the OLED display is reduced, thereby making the OLED display more compact. In addition, the touch wire 40 and any one or more of the anode, the data line, and the scanning line are fabricated from the same materials in the same process, which is good to lessen the production processes and reducing the production cost. According to the distance between the touch wire 40 and the bonding terminal 30, the width of the touch wire 40 and the number of metal layer are adjusted flexibly, which is good to reduce the difference between different touch wires 40 but enhancing the sensitivity of touch.

While the present invention has been described in connection with what is considered the most practical and preferred embodiments, it is understood that this invention is not limited to the disclosed embodiments but is intended to cover various arrangements made without departing from the scope of the broadest interpretation of the appended claims.

What is claimed is:

1. An organic light emitting diode (OLED) display, comprising:
a substrate;
a buffer layer, arranged on the substrate;
a semiconductor layer, arranged on the buffer layer;
a gate insulating layer, arranged on the buffer layer and covering the semiconductor layer;
a first metal layer, arranged on the gate insulating layer and comprising a gate metal line and a scanning line;
an interlayer insulating layer, arranged on the gate insulating layer and covering the first metal layer;
a second metal layer, arranged on the interlayer insulating layer and comprising a source-drain metal trace and a data line;
a planar layer, arranged on the interlayer insulating layer and covering the second metal layer;
an anode metal layer and a pixel definition layer, arranged on the planar layer; the anode metal layer comprising an anode;
a cathode metal layer, arranged on the pixel definition layer; and
a bonding terminal;
wherein a spacing member above the pixel definition layer is arranged on the cathode metal layer; the spacing member divides the cathode metal layer into two or more mutually independent sensing electrodes; each of the sensing electrodes is electrically connected to the bonding terminal through a touch wire; the touch wire is arranged below one layer of the cathode metal layer.

2. The OLED display of claim 1, wherein the touch wire and the anode are arranged in the same layer and independent of each other; a first hole is arranged on the pixel definition layer; the sensing electrode is electrically connected to the touch wire through the first hole.

3. The OLED display of claim 2, wherein the anode metal layer comprises the anode and the touch wire; the touch wire and the anode are fabricated in the same manufacturing process.

4. The OLED display of claim 1, wherein the touch wire and the data line are arranged in the same layer and independent of each other; a second hole is arranged on the pixel definition layer and penetrates the pixel definition layer and the planar layer; the sensing electrode is electrically connected to the touch wire through the second hole.

5. The OLED display of claim 4 wherein the second metal layer comprises the data line and the touch wire; the touch wire and the data line are fabricated in the same manufacturing process.

6. The OLED display of claim 1, wherein the touch wire and the scanning line are arranged in the same layer and independent of each other; a third hole is arranged on the pixel definition layer and penetrates the pixel definition layer, the planar layer, and the interlayer insulating layer; the sensing electrode is electrically connected to the touch wire through the third hole.

7. The OLED display of claim 6, wherein the first metal layer comprises the scanning line and the touch wire; the touch wire and the scanning line are fabricated in the same manufacturing process.

8. The OLED display of claim 1, wherein the touch wires comprise two or more of the first metal layer, the second metal layer, and the anode metal layer; the metal layers arranged between different but adjacent layers in the touch wire are electrically connected through a joint hole; the metal layer arranged in the top layer of the touch wire is electrically connected to the corresponding sensing electrode through a fourth hole.

9. The OLED display of claim 8, wherein the touch wire which the sensing electrode away from the bonding terminal is connected to comprises two or more of the first metal layer, the second metal layer, and the anode metal layer.

10. The OLED display of claim 1, wherein the width of the touch wire which the sensing electrode is connected to is directly proportional to the distance between the sensing electrode and the bonding terminal.
